(19) United States
(12) Patent Application Publication
(10) Pub. No.: US 2026/0163407 A1
(43) Pub. Date: Jun. 11, 2026

(54) WIRELESS CHARGER MOUNTING SYSTEM

(71) Applicant: Annex Products Pty. Ltd., South Yarra (AU)

(72) Inventors: Christopher L. PETERS, South Yarra (AU); Marco SEBASTIANI, South Yarra (AU)

(21) Appl. No.: 19/449,073

(22) Filed: Jan. 14, 2026

Related U.S. Application Data
(63) Continuation of application No. 17/859,512, filed on Jul. 7, 2022, now Pat. No. 12,531,435.
(60) Provisional application No. 63/290,799, filed on Dec. 17, 2021.

(51) Int. Cl. H02J 50/00; A45C 11/00; H02J 7/70; H04B 1/3883; H04B 1/3888; H04M 1/02; H04M 1/04; H04M 1/21

(52) U.S. Cl. CPC H02J 50/005; A45C 11/00; H02J 7/70; H04B 1/3883; H04B 1/3888; H04M 1/0274; H04M 1/04; H04M 1/21; A45C 11/002

(57) ABSTRACT

A system for mounting a wireless cellphone charger to a cellphone, including a cellphone case and a wireless cellphone charger mount. The cellphone case defines a bore and a recess disposed adjacent the bore and includes a shell and a first retention ring having a first metal plate receivable by the recess to secure the first retention ring to the shell. The wireless cellphone charger mount has a wireless cellphone charger, a second metal plate and an interface comprising a protrusion receivable by the bore. The wireless cellphone charger is securable to the cellphone case when the first retention ring is secured to the shell by aligning the protrusion and the bore and magnetically coupling the first and second metal plates.

### CROSS REFERENCE TO RELATED APPLICATION

This application is a continuation of U.S. application Ser. No. 17/859,512, filed Jul. 7, 2022, which claims priority to U.S. Provisional Application No. 63/290,799, filed Dec. 17, 2021. The disclosure set forth in the referenced applications are incorporated herein by reference in their entirety.

### BACKGROUND AND SUMMARY

The present disclosure relates generally to a mounting system for mounting a wireless cellphone charger to a cellphone case.

The present disclosure is directed to a system for mounting a wireless cellphone charger to a cellphone case for charging a cellphone when the cellphone is secured to the cellphone case. The system includes a cellphone case and a wireless cellphone charger mount. The cellphone case defines a bore and a recess disposed adjacent the bore and includes a shell and a first retention ring having a first metal plate receivable by the recess to secure the first retention ring to the shell. The wireless cellphone charger mount has a wireless cellphone charger, a second metal plate and an interface comprising a protrusion receivable by the bore. The wireless cellphone charger is securable to the cellphone case when the first retention ring is secured to the shell by aligning the protrusion and the bore and magnetically coupling the first and second metal plates. At least one of the first and second metal plates is a magnet. The other of the first and second metal plates may be a magnet or may include another metal that is attracted to the magnet of said one of the first and second metal plates.

The recess and the first and second metal plates may be circular and the recess may be disposed about the bore. The bore may include a central bore and at least one lateral slot contiguous with the central bore, and the protrusion may have at least one lateral tab received by the slot when the protrusion is received by the bore. There may, for example, be four lateral slots contiguous with the central bore and spaced 90 degrees apart, and the protrusion may have four lateral tabs spaced 90 degrees apart and received by the slots when the protrusion is received by the bore. The shell may have a rim configured to engage a cellphone and a base having a bottom defining the bore and recess. The mounting system may also include a pick and the shell may include a top defining at least one hole. The hole may be accessible by the pick from the top for separating the first retention ring from the cellphone case when the first retention ring is secured to the cellphone case.

The mounting system may also include at least one alternate first retention ring having an alternate first metal plate. The at least one alternate first retention ring is receivable by the recess and securable to the cellphone case as an alternate to the first retention ring. The color of the retention ring may be different than the color of the alternate retention ring.

In accordance with some embodiments, the cellphone case may be engageable with cellphone accessory mount products. In accordance with some embodiments, the first and second metal plates may be compatible with the magnetic technology known as MAGSAFE Apple Computer, Inc. (“Apple”) developed for magnetically securing or otherwise mounting iPhone products to accessory products.

These and other features of the present disclosure will be best understood from the following drawings and detailed description.

### BRIEF DESCRIPTION OF THE DRAWINGS

The various features and benefits of the present disclosure will become apparent to those skilled in the art from the following detailed description of the illustrated embodiments. The drawings that accompany the detailed description can be briefly described as follows:

FIG. 1(a) is a perspective of one side of a mounting system in accordance with an illustrated embodiment including a wireless charger mount and a cellphone case;

FIG. 1(b) is a perspective of the other side of the mounting system of FIG. 1(a);

FIG. 2(a) is an exploded perspective of one side of the cellphone case of the mounting system of FIG. 1(a) and 1(b);

FIG. 2(b) is an exploded perspective of the other side of the cellphone case of the mounting system of FIG. 1(a) and 1(b);

FIG. 3(a) is an exploded perspective of one side of the wireless charger mount of the mounting system of FIG. 1(a) and 1(b);

FIG. 3(b) is an exploded perspective of the other side of the wireless charger mount of the mounting system of FIG. 1(a) and 1(b);

FIG. 4 is a cross section taken along the center of the cellphone case of the mounting system of FIG. 1(a) and 1(b);

FIG. 5 is a cross section of the mounting system of FIG. 1(a) and 1(b) with the cellphone case mounted to the wireless charger mount and a cellphone mount accessory secured thereto; and

FIG. 6 is an example of a commercially-available cellphone accessory mount that can be secured to the cellphone case of the mounting system of FIG. 1(a) and 1(b) when the wireless charger mount is separated from the cellphone case.

Other aspects and advantages of the present disclosure will become apparent upon consideration of the following detailed description.

### DETAILED DESCRIPTION

While the present disclosure may be embodied in many different forms, several specific embodiments are discussed herein with the understanding that the present disclosure is to be considered only as an exemplification of the principles of the disclosure, and it is not intended to limit the disclosure to the embodiments illustrated.

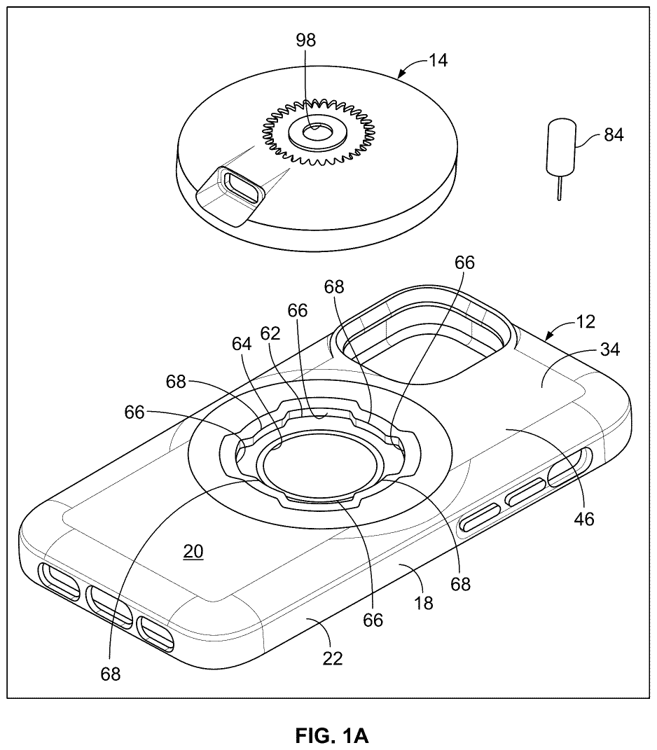

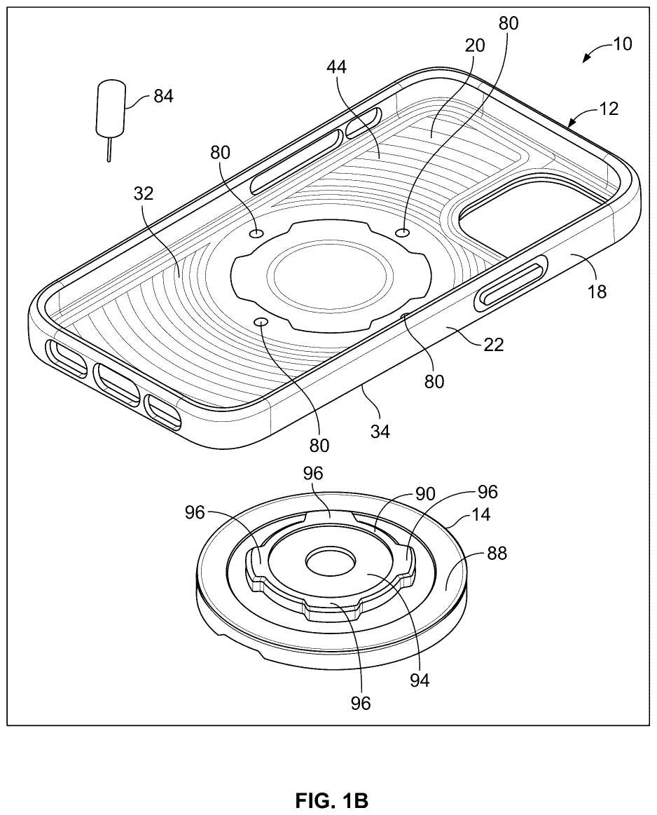

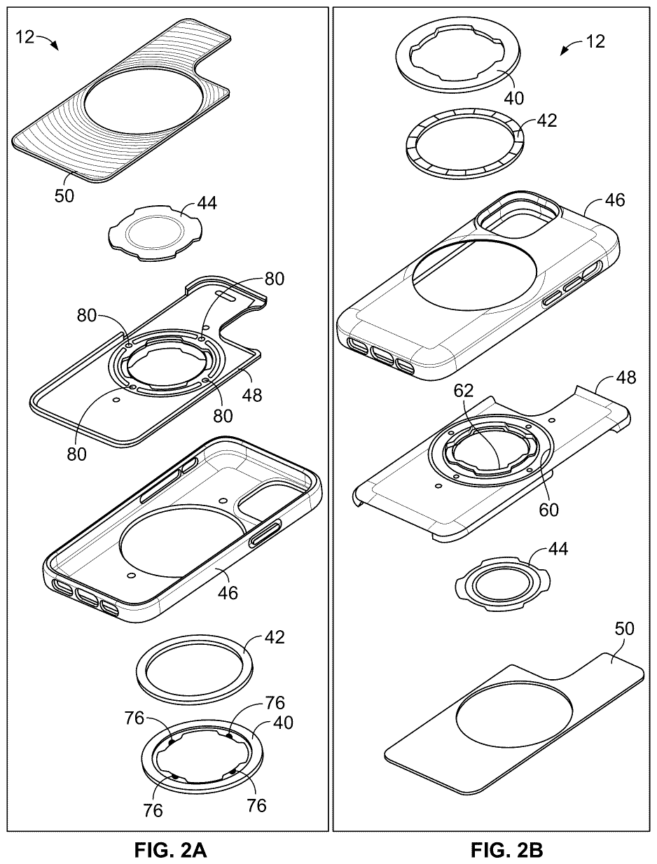

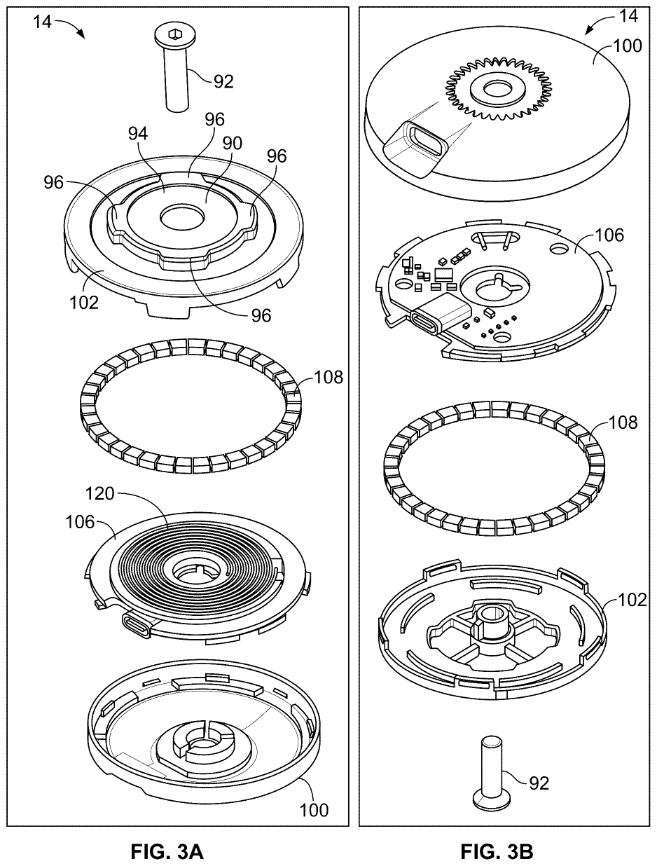

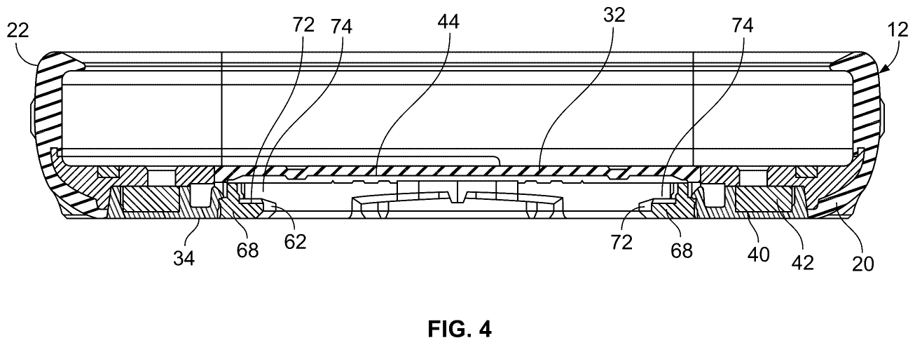

FIGS. 1-5 illustrate a mounting system 10 including a cellphone case 12 and a wireless cellphone charger mount 14 for charging a cellphone when the wireless charger mount and cellphone are secured to the cellphone case. In accordance with illustrated embodiments, and as described below, the cellphone case 12 can be mounted to other cellphone accessory mount products when the wireless charger mount 14 is separated from the cellphone case 12. The cellphone may be an iPhone or any other handheld cellphone. The mounting system 10 can be used, for example, with Apple's magnetic technology for iPhone products known as MAGSAFE in accordance with an embodiment of the present disclosure.

The cellphone case 12 case includes a shell 18 having a base 20 and a rim 22 for engaging the cell phone. The base 20 includes a top 32 and a bottom 34. The cellphone case 12 further includes several components secured together, including a retention ring 40, a metal plate 42 secured to the retention ring, an internal plate 44 and three casing members including an outer casing member 46, an inner casing member 48 and an internal lining 50. The base 20 includes the casing members 46, 48 and 50. The metal plate 42 is circular and may be in the form of a magnet or a metal plate that includes another metal that is attracted to a magnet. The bottom 34 defines a recess 60 for receiving the retention ring 40 and a bore 62 for engaging the wireless charger mount 14. The recess 60 is circular and is disposed about or otherwise surrounds the bore 62. The bore 62 includes a central bore 64 and four lateral slots 66 contiguous with the central bore 64 spaced 90 degrees apart. Four case tabs 68 spaced 90 degrees apart are disposed between the lateral slots 66 and form notches 72 defining gaps 74. The gaps 74 are also contiguous with the central bore 64 and lateral slots 66. The metal plate 42 may be in the form of a circular magnetic array that is compatible with Apple's MAGSAFE technology. The recess 60 and bore 62 may have any other suitable configuration and the recess may be adjacent the bore in any other suitable manner in accordance with other embodiments of the present disclosure.

The retention ring 40 includes clips 76. The retention ring 40 is snapped into the recess 60 of the cellphone case 12 and retained therein by the clips 76. The illustrated embodiment of the cellphone case 12 defines four holes 80 contiguous with the recess 60, 62 and the mounting system 10 further includes a pick 84. The pick 84 can access any of the holes 80 from the top 32 of the base 20 for dislodging and removing the retention ring 40 from the recess 60 of the cellphone case 12. The pick 84 may have any suitable construction.

The mounting system 10 may include a plurality of the retention rings 40 so that the user may have a choice of retention rings and can change the appearance of the cellphone case 12. For example, each of the plurality of the retention rings 40 may be of a color different than the colors of the or more other retention rings so that the user can select to secure to the cellphone case 12 a retention ring of a desired color.

The internal plate 44 may be ultrasonically welded to the inner casing member 48. This construction may eliminate openings and allow for the internal plate 44 to be reduced in thickness without comprising strength. The reduction in thickness or depth of the cellphone case allows the phone to efficiently wirelessly charge using an Apple MAGSAFE wireless charger or other suitable wireless charger.

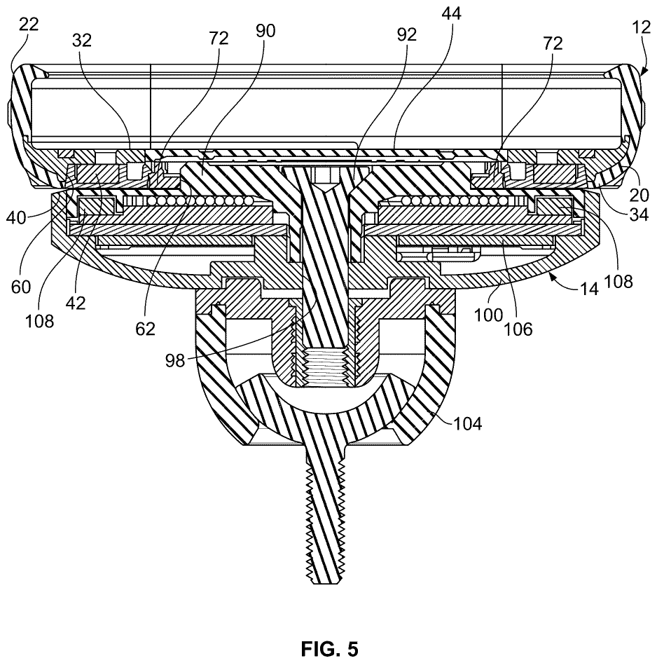

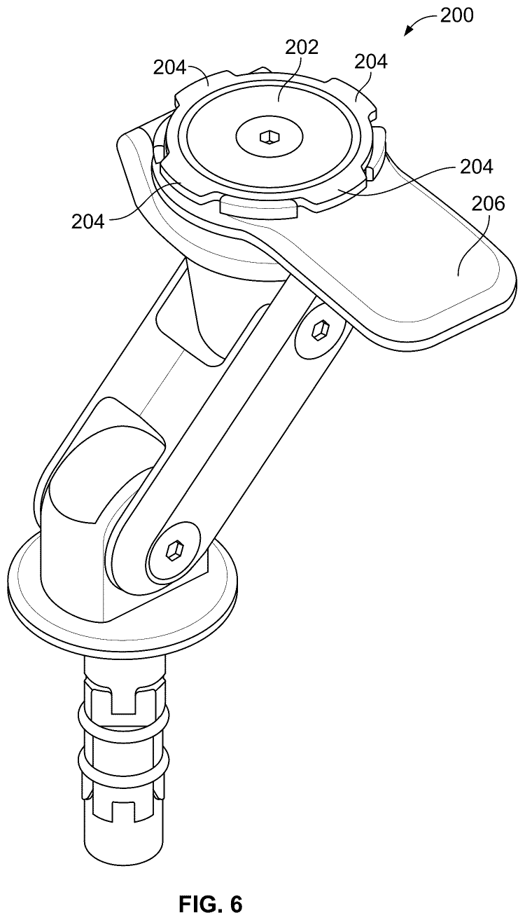

The wireless interface of the wireless charger mount 14 further includes a mount base 88 and a protrusion 90 extending from the mount base substantially parallel to a longitudinal axis of the mount base. The protrusion 90 has a central portion 94 and four lateral tabs 96 spaced 90° apart. The wireless charger mount 14 includes a fastener 92 received by hole 98 defined by the wireless charger mount for engaging a cellphone accessory product 104 (see, e.g., FIG. 5). The illustrated wireless charger mount 14 further includes a casing 100, a base 102, a wireless charger 106 and a metal plate 108 housed within the casing. The metal plate 108 may be in the form of a magnet or a metal plate that includes a metal that is attracted to a magnet. The metal plate 108 may be in the form of a circular magnet array that corresponds with the metal plate 42 of the cellphone case 12 to attract the cellphone case 12 to the wireless charger mount 14. The metal plate 108 may have any other suitable configuration in accordance with other embodiments of the present disclosure. The metal plate 108 may also be compatible with Apple's MAGSAFE technology.

The wireless charger mount 14 may be powered by any suitable power source (not shown) including any suitable cable connected to the wireless charger mount 14 in any suitable manner for providing power to the transmitting coil 120. The cellphone case 12 and the casing 100 and the base 102 may be constructed of any suitable plastic or any other suitable material and may have any other suitable configuration in accordance with other embodiments of the present disclosure.

The illustrated mounting system 10 may also be characterized as having two slots 66 extending laterally from the central bore 64 and spaced 180 degrees apart, and the protrusion 90 of the wireless charger mount 14 as having two lateral tabs 96 spaced 180 degrees apart. In this regard, the mounting system in accordance with embodiments of the present disclosure, the bore may have more or less than two slots and the protrusion may have more or less than four lateral tabs.

During securement of the cellphone case 12 to the wireless charger mount 14, the protrusion 90 of the wireless charger mount 14 is aligned with the bore 62, including aligning the lateral tabs 96 and the lateral slots 66. The metal plates 42 and 108 are then magnetically coupled together with the bore 62 receiving the protrusion 90 and the slots 66 receiving the lateral tabs 96. Metal plates 42 and 108 may both be magnets or one of the metal plates 42 and 108 can be a magnet and the other metal plate can be a metal that is attracted to said one of the metal plates 42 and 108. The metal plates 42 and 108 are illustrated as being circular but they may have any other configuration in accordance with other embodiments of the present disclosure. The mechanical alignment along with the magnetic attraction provides more robust alignment and shear strength than common flat magnetic mounts. Once mounted, because the lateral tabs 96 extend from the mount base 88 substantially parallel to the longitudinal axis of the mount base 88, the cellphone case 12 in accordance with the illustrated embodiment cannot be rotated relative to the wireless charger mount 14 unless it is separated from the wireless charger mount. The wireless charger 106 functions to charge the cellphone. The wireless charger mount 14 can be readily unsecured from the cellphone case 12 by applying a force greater than the magnetic force of the metal plates 42 and 108.

The interface on the bottom 34 of the cellphone case 12 may complement the interface of one or more cellphone accessory mount products so that the cellphone case may also be secured to other cellphone accessory mount products when the wireless charger mount 14 is removed is not secured to the cellphone case. Examples of such cellphone accessory mount products are disclosed, for example, in U.S. Pat. Nos. 11,303,143, D941,760, D940,125, D883,922, 10,649,492, D876,316, 10,569,717, D873,812, D870,719, D870,718, D865,252, D852,681, 9,243,739. As a further example, FIG. 6, illustrates a commercially-available cellphone accessory mount product 200 having an interface comprising a protrusion 202 having four lateral tabs 204 spaced 90 degrees apart and a lever 206 configured to be received by the bore 62 when the wireless charger mount 14 is not secured to the cellphone case and when the lever is pressed to define gaps beneath the lateral tabs. The interface of the accessory product is received by the bore 62 and, upon rotation of 90 degrees (or 90 degree increments), the tabs 204 are received within the gaps 74 of the cellphone case 12 and engage the bottom of the notches 72 to engage the accessory 200 to the cellphone case 12.

Accordingly, the present disclosure provides several benefits. For example, it provides an efficient manner of securing a wireless charger mount to a cellphone case to wirelessly charge a cellphone secured to the cellphone case. Further, if desired, the cellphone case 12 can be secured to other cellphone accessory mount products when the wireless charger mount 14 is secured to the cellphone case (see, e.g., FIG. 6). Still further, because of the interface of the cellphone case 12, the cellphone case can be secured to other cellphone accessory mount products such as the accessory products shown in FIG. 6 and U.S. Pat. Nos. 11,303,143, D941,760, D940,125, D883,922, 10,649,492, D876,316, 10,569,717, D873,812, D870,719, D870,718, D865,252, D852,681, 9,243,739.

In accordance with other embodiments of the present disclosure, the magnetic system can be used as a magnetic mount without a wireless charger.

Numerous modifications to the present invention will be apparent to those skilled in the art in view of the foregoing description. Accordingly, this description is to be construed as illustrative only and is presented for the purpose of enabling those skilled in the art to make and use the invention and to teach the best mode of carrying out same. The exclusive rights to all modifications, which come within the scope of the appended claims, are reserved.

1.-21. (canceled)

22. A case for an electronic device comprising:
a shell comprising a base and a rim configured to engage the electronic device, wherein a recess is formed in a bottom surface of the base, wherein the recess comprises an inner perimeter wall and an outer perimeter wall; and
a retention ring disposed in the recess,
wherein the retention ring is moveably coupled to the shell.

23. The case of claim 22, further comprising a metal plate coupled to the retention ring.

24. The case of claim 2, wherein the metal plate is a magnet.

25. The case of claim 22, wherein the retention ring is circular and surrounds an entire perimeter of a bore formed through the shell.

26. The case of claim 22, wherein the base further comprises an aperture formed through the recess.

27. The case of claim 26, further comprising a pick configured to be inserted through the aperture for separating the retention ring from the shell.

28. The case of claim 22, further comprising at least one alternate retention ring removably coupled to the shell as an alternative to the retention ring.

29. The case of claim 28, wherein the retention ring is removeably coupled to the shell.

30. The case of claim 22, wherein the retention ring comprises a plurality of clips that couple to the recess of the shell.

31. The case of claim 30, wherein the retention ring couples to the shell with a snap-fit connection.

32. A case for an electronic device comprising:
a shell comprising a base wall, a bore formed through the base wall, a plurality of lateral slots and a plurality of case tabs surrounding the bore, the slots and case tabs alternately disposed to form notches configured to receive mounting tabs of a mounting accessory, and a recess formed in a bottom surface of the base wall and surrounding the bore; and
a retention ring coupled to the shell and disposed in the recess.

33. The case of claim 32, wherein the retention ring is removeably coupled to the shell with a snap-fit connection.

34. The case of claim 32, wherein the shell comprises and inner casing and an outer casing, wherein the outer casing comprises a rim configured to engage the electronic device.

35. The case of claim 32, wherein the retention ring comprises a ring recess and a metal plate is disposed in the ring recess.

36. The case of claim 35, wherein the metal ring magnetically couples with the mounting accessory.

37. The case of claim 32, wherein the recess surrounds an entire perimeter of the bore.

38. The case of claim 32, wherein the retention ring comprises a metal plate and a plurality of clips configured to couple to the recess of the shell.

39. The case of claim 38, wherein the plurality of clips extend radially inward and engage the recess with a snap-fit connection.

40. The case of claim 38, wherein the metal plate is a circular magnetic array.

41. The case of claim 32, further comprising at least one alternate retention ring removably coupled to the shell as an alternative to the retention ring.
